(19) United States
(12) Patent Application Publication
(10) Pub. No.: US 2013/0153149 A1
(43) Pub. Date: Jun. 20, 2013

(54) Substrate Processing Tool with Tunable Fluid Flow

(71) Applicants: Danny Wang, Saratoga, CA (US); Kent Riley Child, Dublin, CA (US); James Tsung, Milpitas, CA (US); Hong Sheng Yang, Pleasanton, CA (US)

(72) Inventors: Danny Wang, Saratoga, CA (US); Kent Riley Child, Dublin, CA (US); James Tsung, Milpitas, CA (US); Hong Sheng Yang, Pleasanton, CA (US)

(73) Assignee: Intermolecular, Inc., San Jose, CA (US)

(21) Appl. No.: 13/331,011

(22) Filed: Dec. 20, 2011

(51) Int. Cl. C23F 1/08; F17D 3/00; C23C 16/458

(52) U.S. Cl. 156/345.51; 118/728; 137/1

(57) ABSTRACT

Embodiments provided herein describe substrate processing tools. The substrate processing tools include a housing defining a processing chamber. A substrate support is coupled to the housing and configured to support a substrate within the processing chamber. The substrate has a central axis. A first annular member is moveably coupled to the housing and positioned within the processing chamber. The first annular member circumscribes the central axis of the substrate. A second annular member is moveably coupled to the housing and positioned within the processing chamber. The second annular member circumscribes the central axis of the substrate. Movement of the first annular member and the second annular member relative to the housing changes a flow of processing fluid through the processing chamber.

The present invention relates to substrate processing. More particularly, this invention relates to substrate processing tools with tunable fluid flow through the processing chambers thereof.

### BACKGROUND OF THE INVENTION

Materials, such as thin films, are often deposited on substrates, such as semiconductor or glass substrates, in devices known as substrate processing tools. In order to deposit the materials, processing fluids (e.g., gases) are delivered into processing chambers within the tools, where the substrate to be processed is positioned. Examples of such processing techniques include chemical vapor deposition (CVD) and physical vapor deposition (PVD). Similar processing tools may be used for removing material from substrates (e.g., etching), as well as for purging steps associated with, for example, CVD, PVD, and etching.

Depending on the particular processing technique being used, or the materials involved, the characteristics of the flow of the processing fluids through the processing chamber may be important to successful processing. One particular example of such a process is the formation of graphene, which typically requires a particular flow rate and relatively laminar flow over the substrate being processed.

However, due to the design of most conventional processing tools, particularly the shape of the processing chambers, it is difficult to achieve optimal flow of the processing fluids, as the flow is often non-uniform and includes undesirable turbulence.

### BRIEF DESCRIPTION OF THE DRAWINGS

Various embodiments of the invention are disclosed in the following detailed description and the accompanying drawings:

FIG. 1 is a cross-sectional view of a substrate processing tool according to an embodiment of the present invention;

FIG. 2 is an isometric view of a first flow adjustment ring and a second flow adjustment ring according to an embodiment of the present invention;

FIG. 3 is a cross-section view of a substrate processing tool according to an embodiment of the present invention, which may be taken along line 3-3 in FIG. 1;

FIG. 4 is a cross-sectional view of a substrate processing tool according to an embodiment of the present invention;

FIG. 5 is a cross-sectional view of a portion of a substrate processing tool according to an embodiment of the present invention; and

FIG. 6 is a schematic view of a substrate processing system according to an embodiment of the present invention.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

Embodiments described herein provide substrate processing tools, which allow for adjustments to be made to various aspects of the flow of processing fluids (e.g. gases) through the processing chamber. This is accomplished by providing a process kit having an enclosure within the processing chamber that encloses the substrate support, along with two annular members (or rings) within the enclosure that may be positioned or moved in such a way to tune the flow of gas during processing. Adjustments made to the annular members allow for the tuning of gas flow and conductance, volume, and pressure, along with providing laminar flow over the substrate.

The process kit may be used, for example, in various dry processing techniques, such as chemical vapor deposition (CVD), physical vapor deposition (PVD), and etching, as well as purge steps associated with those techniques. The process kit may be particularly useful for the formation of graphene, in which controlling the various properties of gas flow may be particularly important.

In some embodiments, a substrate processing tool is provided that includes a housing defining a processing chamber and a substrate support coupled to the housing and configured to support a substrate within the processing chamber. A first annular member is moveably coupled to the housing and positioned within the processing chamber. The first annular member circumscribes a central axis of the substrate. A second annular member is moveably coupled to the housing and positioned within the processing chamber. The second annular member circumscribes the central axis of the substrate. Movement of the first annular member and the second annular member relative to the housing changes a flow of processing fluid through the processing chamber.

The first annular member may be vertically moveable within the processing chamber. The second annular member may be horizontally moveable and/or angularly moveable within the processing chamber. The substrate support, the first annular member, and the second annular member may be surrounded by an enclosure within the processing chamber. The enclosure may also have one or more exhaust openings symmetrically arranged around the central axis of the substrate, which may be selectively closed (e.g., completely or partially) by a user. The enclosure and the annular members may be made of, for example, quartz or polytetrafluoroethylene (PTFE), depending on the processing techniques to be performed in a particular tool.

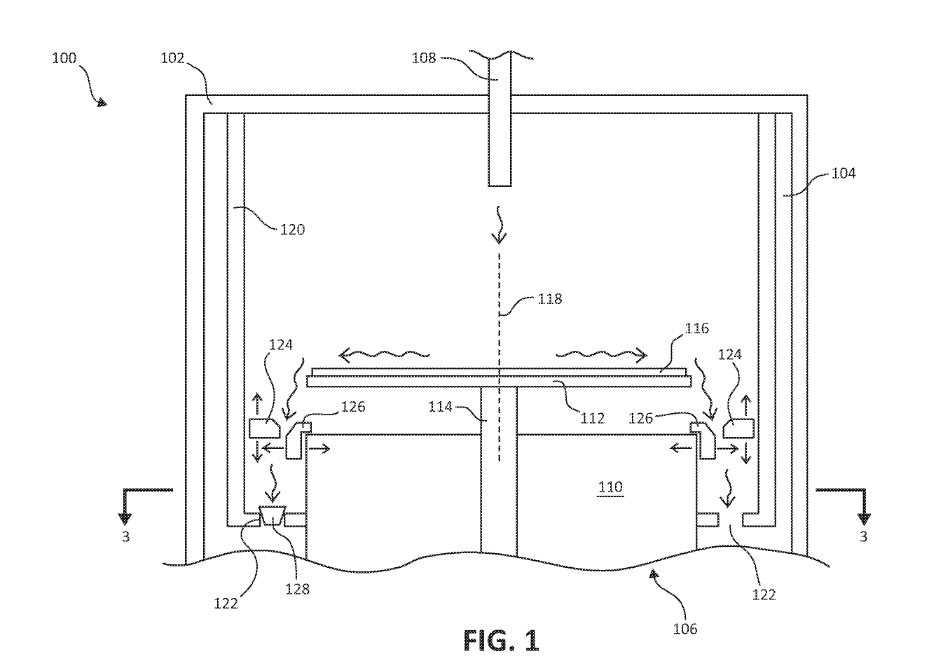

FIG. 1 is a simplified view of a substrate processing tool 100 according to some embodiments of the present invention. The substrate processing tool 100 includes a housing 102 that defines a processing chamber 104, a support assembly 106, and a processing fluid inlet 108.

The support assembly 106 is coupled to the housing 102 at a lower portion thereof includes a base 110 and a substrate support 112. The base 110 extends into a central portion of the processing chamber 104, and the substrate support 112 is coupled to the base 110 by a support shaft 114 and configured to support a substrate 116 within the processing chamber 104. The substrate 116 may be, for example, a semiconductor substrate (e.g., made of silicon) or a transparent substrate (e.g., made of glass) with, for example, a diameter of 200 or 300 millimeters (mm). The substrate 116 has a central axis 118 that extends through a central portion of the substrate support 112 and the base 110 when the substrate 116 is positioned on the substrate support 112 as shown.

The processing fluid inlet 108 is coupled to the housing 102 and extends into the processing chamber 104 above the central axis 118 of the substrate 116. Although not shown in FIG. 1, the processing fluid inlet 108 may be in fluid communication with a processing fluid supply (e.g., containing processing gases).

Still referring to FIG. 1, the substrate processing tool 100 also includes an enclosure 120 coupled to the housing 102 and positioned within the processing chamber 104. As shown, the enclosure 120 surrounds the support assembly 106 (as well as the substrate 116) and the processing fluid inlet 108. As such, the enclosure 120 may essentially reduce the size of the processing chamber 104. At a lower portion thereof, the enclosure 120 includes a series of exhaust ports 122. As is described below, in some embodiments, the exhaust ports 122 are arranged around the central axis 118 of the substrate 116.

Further, the substrate processing tool 100 includes a first flow adjustment ring 124 and a second flow adjustment ring 126 positioned within the enclosure 120. As shown in FIG. 1, the first flow adjustment ring (or first annular member) 124 extends around an upper portion of the base 110 of the support assembly 106. Thus, the first flow adjustment ring 124 also circumscribes the central axis 118 of the substrate 116. In some embodiments, the first flow adjustment ring 124 is moveably coupled to the housing 102 such that it may be moved vertically within the enclosure 120 (and/or the processing chamber 104), or more specifically, in a direction that is substantially parallel with the central axis 118 of the substrate 116. As shown in FIG. 1, the first flow adjustment ring 124 and the second flow adjustment ring 126 both have a width (or diameter) that is greater than a width (or diameter) of the substrate support 112, with the width of the first flow adjustment ring 124 being greater than that of the second flow adjustment ring 126.

In the depicted embodiment, the second flow adjustment ring 126 also extends around the upper portion of the base 110 of the support assembly 106 and is positioned between the base 110 and the first flow adjustment ring 124. In some embodiments, the second flow adjustment ring 126 is moveably coupled to the housing 102 such that it may be moved horizontally within the enclosure 120, or more specifically, in a direction that is perpendicular to the central axis 118 of the substrate 116. It should be noted that in at least one embodiment, the second flow adjustment ring 126 is moveable in two dimensions (e.g., a plane) so that as viewed in FIG. 1, it may be moved to the left and the right, as well as into and out of the page on which FIG. 1 is shown.

Still referring to FIG. 1, the substrate processing tool 100 includes one or more exhaust port plugs 128. According to some embodiments of the present invention, the exhaust ports plugs 128 may be selectively inserted into the exhaust ports 122. Each of the exhaust port plugs 128 restrict (e.g., partially or completely) the flow of processing fluid (e.g., gas) through the respective exhaust port 122.

During processing, a substrate processing fluid (e.g., a gas) is delivered into the processing chamber 104, or more particularly, within the enclosure 120 through the processing fluid inlet 108, while a vacuum is applied to a lower portion of the processing chamber 104. The processing fluid impinges the substrate 116 and spreads out radially away from the central axis 118 of the substrate 116. The processing fluid flows off the substrate 116, passes between the first flow adjustment ring 124 and the second flow adjustment ring 126, and is removed from the enclosure 120 through the exhaust ports 122.

In accordance with some embodiments of the present invention, a user may tune the properties of the flow of the processing fluid, particularly across the substrate 116, by adjusting the position of the first flow adjustment ring 124 and the position of the second flow adjustment ring 126. For example, a user may adjust the conductance of the flow by raising (i.e., to increase conductance) or lowering (i.e., to decrease conductance) the first flow adjustment ring 124. As another example, a user may tune the flow to increase the uniformity of the flow and the amount of laminar flow across the substrate 116 by adjusting the position of the second flow adjustment ring 126. The various properties of the flow of the processing fluid, such as the amount of laminar flow across the substrate 116, may be further adjusted selectively restricting flow through the exhaust ports 122 using the exhaust port plugs 128.

Additionally, in other embodiments, the first flow adjustment ring 124 and/or the second flow adjustment ring 126 may be coupled to the housing such that the user may tilt (i.e., change the angular orientation thereof) the ring(s) to adjust the properties of the flow of the processing fluid, perhaps in addition to other adjustments made to the ring(s) described above. Further, although the adjustments made to the first flow adjustment ring 124 and the second flow adjustment ring 126 may be made by a user manually in some embodiments, in other embodiments, the positions of the first flow adjustment ring 124 and the second flow adjustment ring 126 may be controlled by one or more actuators that are provided with control signals from a control system, such as that described below.

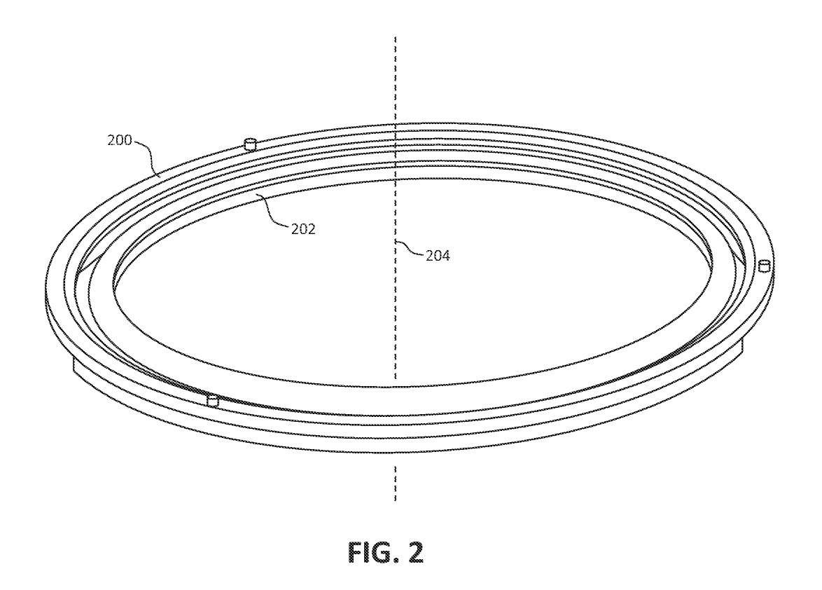

FIG. 2 illustrates a first flow adjustment ring 200 and a second flow adjustment ring 202, which may be similar to those shown in FIG. 1. As shown, both the first flow adjustment ring 200 and the second flow adjustment ring 202 are substantially annular in shape and circumscribe a central axis 204, which may correspond to the central axis of the substrate shown in FIG. 1.

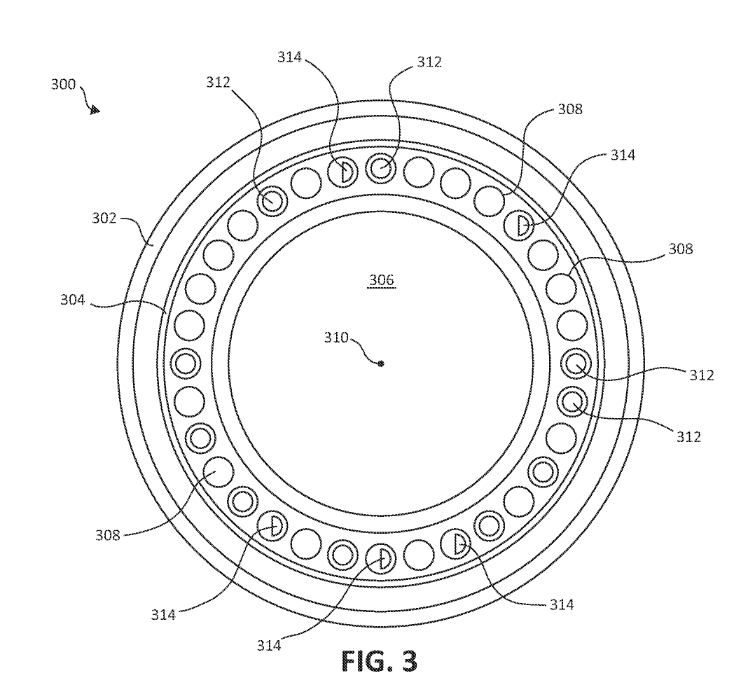

FIG. 3 illustrates a substrate processing tool 300, which may be similar to that shown in FIG. 1 when viewed along 3-3 in FIG. 1. As shown, the substrate processing tool 300 includes components corresponding to those shown in FIG. 1, such as a housing 302, an enclosure 304, and a support assembly base 306. The enclosure 304 includes a series of exhaust ports 308 spaced around the support assembly base 306, as well as an axis 310, which may correspond to the central axis of the substrate shown in FIG. 1. As described above, exhaust port plugs may be selectively inserted into the exhaust ports 308 to further adjust or tune the flow of processing fluid through the enclosure 304.

In the embodiment shown in FIG. 3, the exhaust port plugs include full exhaust port plugs 312 and partial exhaust port plugs 314. As shown, each of the full exhaust port plugs 312 substantially fills the respective exhaust port 308 such that the flow of processing fluid through the exhaust port 308 is completely blocked (or restricted). In contrast, each of the partial exhaust port plugs 314 only partially fills the respective exhaust port 308 such that flow of processing fluid through the exhaust port 308 is only partially restricted. By providing both the full exhaust port plugs 312 and the partial exhaust port plugs 314, the flow of processing gas through the enclosure 304 may be further tuned for to provide optimal conditions for various processing techniques.

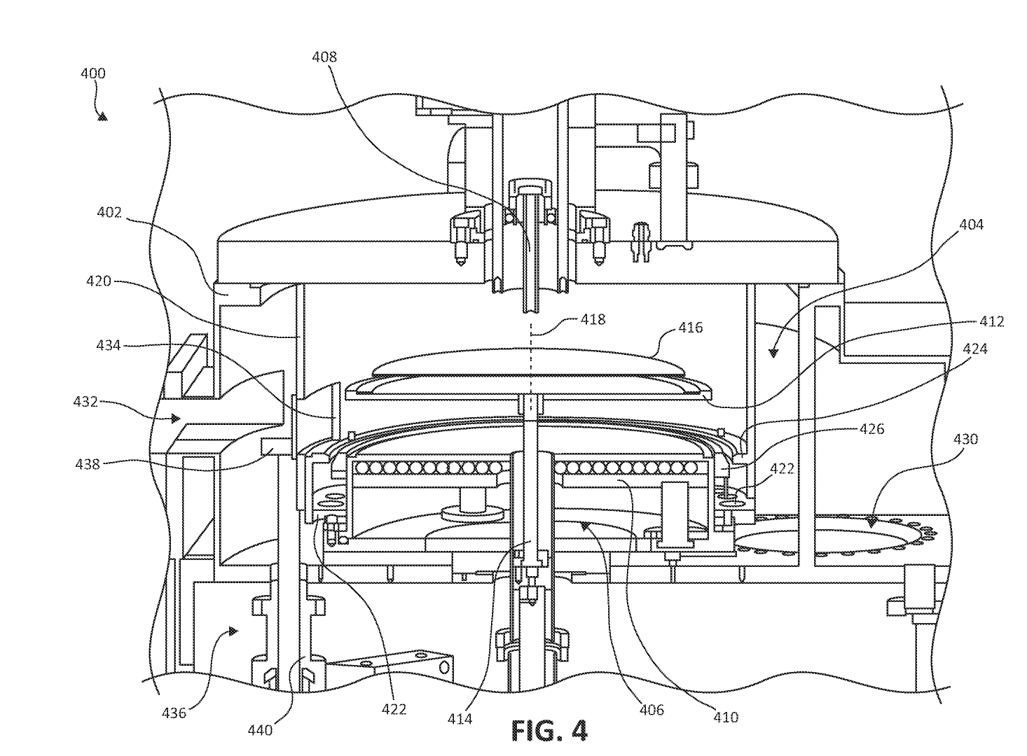

FIG. 4 illustrates a substrate processing tool 400 according to some embodiments of the present invention. The substrate processing tool 400 has components in common with the tool shown in FIG. 1, including a housing 402 defining a processing chamber 404, a support assembly 406, and a processing fluid inlet 408. As in FIG. 1, the support assembly 406 includes a base 410 and a substrate support 412 coupled to the base by a support shaft 414, which is configured to support a substrate 416 having a central axis 418 in the processing chamber 404. Also like the embodiment shown in FIG. 1, the substrate processing tool 400 further includes an enclosure 420 within the processing chamber 404 having a series of exhaust ports 422 at a lower portion thereof, along with a first flow adjustment ring 424 and a second flow adjustment ring 426.

Of particular interest in FIG. 4 is that the housing 402 includes a vacuum port 430 and a (outer) substrate opening 432. The vacuum port 430 extends through a lower portion of the housing 402 and is “offset” from the support assembly 406. More particularly, the vacuum port 430 is not positioned below the substrate 416. As will be appreciated by one skilled in the art, during processing, a vacuum may be applied to the vacuum port 430 to remove processing fluids from the processing chamber 404. The substrate opening 432 extends through the housing 402 on a side thereof substantially opposing the position of the vacuum port 430. As will be appreciated by one skilled in the art, the substrate opening 432 may be use to transport the substrate 416 to and from the processing chamber 404 using, for example, a robotic mechanism. In the embodiment shown in FIG. 4, the enclosure 420 includes a (inner) substrate opening 434 which is aligned with substrate opening 432, such that the substrate 416 may be transported to and from the enclosure 420.

Due to the position of the vacuum port 430 and the presence of substrate opening 432, during conventional processing, the flow of processing gas through the processing chamber 404, particularly over the substrate 416, may include an undesirable lack of laminar flow over the substrate 416 and turbulence. However, as described above, the use of the enclosure 420, along with the first flow adjustment ring 424 and the second flow adjustment ring 426, allows a user to adjust or tune the flow of processing gas to reduce these undesirable effects.

Still referring to FIG. 4, the substrate processing tool 400 further includes an enclosure door assembly 436. The enclosure door assembly 436 includes an enclosure door 438 and an enclosure door actuator 440. As shown in FIG. 4, the enclosure door is sized and shaped to cover the substrate opening 434 through the enclosure and is connected to the enclosure door actuator 440 at a lower portion thereof. The enclosure door actuator 440 may include, for example, one more pneumatic cylinders and be configured to raise and lower the enclosure door 438.

When the enclosure door 438 is raised (as shown in FIG. 4), the substrate opening 434 through the enclosure 420 is substantially covered. During processing, the enclosure door 438 may serve to reduce any turbulence in the flow of processing fluid through the enclosure 420 which may be caused by the presence of the otherwise opened, uncovered substrate opening 434.

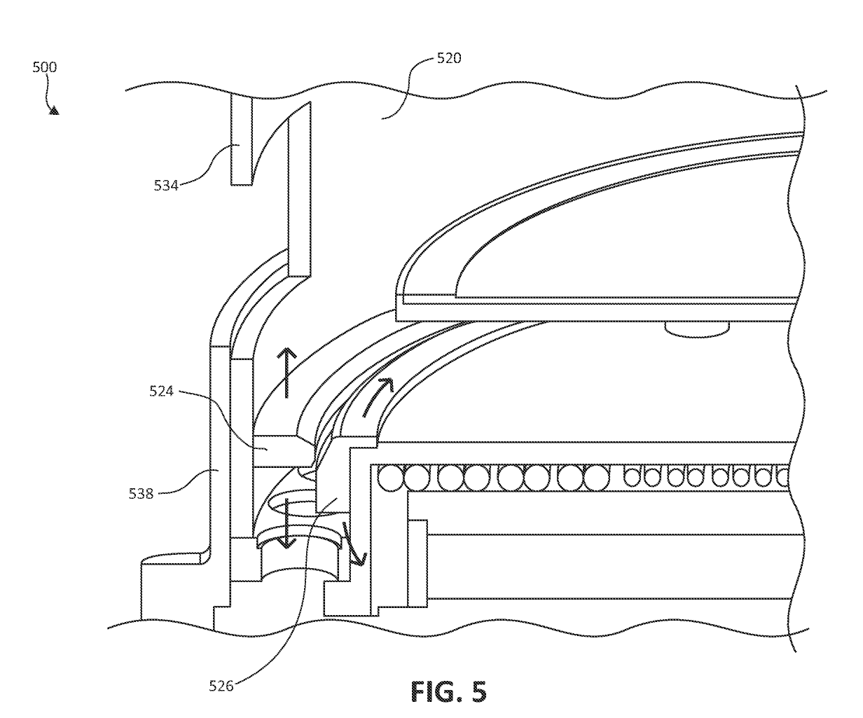

FIG. 5 illustrates a portion of a substrate processing tool 500 that may be similar to that shown in FIG. 4. The substrate processing tool 500 includes an enclosure 520 with a substrate opening 534, a first flow adjustment ring 524, a second flow adjustment ring 526, and an enclosure door 538. Of particular interest in FIG. 5 is that the enclosure door 538 is shown as being lowered, such that the substrate opening 534 is uncovered. Thus, a substrate may be transported through the substrate opening 534 into the enclosure 520.

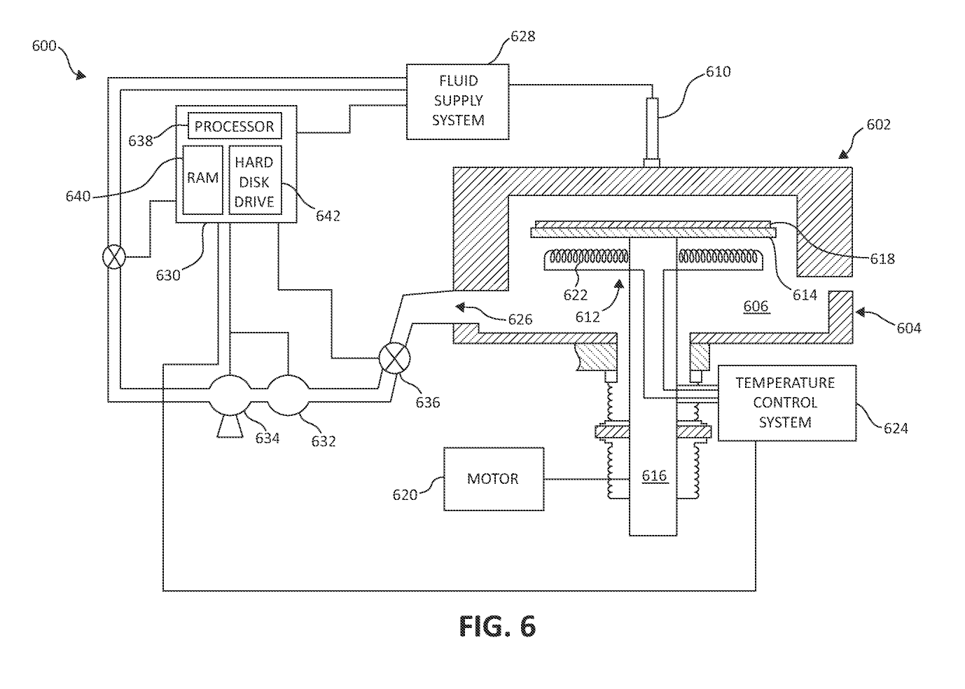

FIG. 6 is a simplified illustration a substrate processing system 600 in accordance with some embodiments of the present invention. The substrate processing system 600 includes a substrate processing tool 602, which may be similar to any of the substrate processing tools described above. In the simplified illustration shown in FIG. 6, the substrate processing tool 602 includes a housing 604, which defines a processing chamber 606. Although only shown in cross-section, it should be understood that the processing chamber 606 is enclosed on all sides by the housing 604.

A processing fluid injection assembly (or inlet) 610 is mounted to an upper portion of the housing 604 and in fluid communication with the processing chamber 606. The substrate processing tool 602 also includes a support assembly 612 disposed within the processing chamber 606. The support assembly 612 includes a support pedestal (or substrate support) 614 connected to an upper portion of a support shaft 616. The support pedestal 614 may be formed from any process-compatible material, including aluminum nitride and aluminum oxide. The support pedestal 614 is configured to hold or support a substrate 618. The substrate 618 may be, for example, a semiconductor substrate (e.g., silicon) having a diameter of, for example, 200 or 300 mm.

The support pedestal 614 may be a vacuum chuck, as is commonly understood, or utilize other conventional techniques, such as an electrostatic chuck (ESC) or physical clamping mechanisms, to prevent the substrate 618 from moving on the support pedestal 614. The support shaft 616 is moveably coupled to the housing 604 such that the support shaft 616, along with the support pedestal 614, may be rotated, as well as raised and lowered using motors 620.

Additionally, the support assembly 612 includes an inductive heating sub-system that includes one or more conductive coils (or members) 622 mounted below the substrate support 614 that are coupled to a power supply within a temperature control system 624.

The housing 604 and the support pedestal 614 are sized and shaped to create a peripheral flow channel that surrounds the support pedestal 614 and provides a path for fluid flow to a vacuum port (or pump channel) 626 in the housing 604.

Still referring to FIG. 6, the processing system 600 also includes a fluid supply system 628 and a controller (or control system) 630. The fluid supply system 628 is in fluid communication with the processing fluid injection assembly 610 through a sequence of conduits (or fluid lines) and includes supplies of various processing fluids (e.g., gases). The fluid supply system 628 (and/or the controller 630) controls the flow of processing fluids to, from, and within the processing chamber 606 with a pressure control system that includes, in the embodiment shown, a turbo pump 632 and a roughing pump 634. The turbo pump 632 and the roughing pump 634 are in fluid communication with the processing chamber 606 via a butterfly valve 636 through the vacuum port 626.

The controller 630 includes a processor 638 and memory, such as random access memory (RAM) 640 and a hard disk drive 642. The controller 630 is in operable communication with the various other components of the processing system 600, including the turbo pump 632, the temperature control system 624, the fluid supply system 628, and the motors 620 and controls the operation of the entire processing system to perform the methods and processes described herein.

During operation, the processing system 600 establishes conditions in a processing region above the substrate 618 to form a layer of material on the surface of the substrate 618, such as a thin film. The processing technique used to form the material may be, for example, a CVD process, such as atomic layer deposition (ALD) or metalorganic chemical vapor deposition (MOCVD), a PVD process, an etching process, or a purge process. During the formation of the layer, power is provided to the conductive coils 622 by the temperature control system 624 such that current flows through the conductive coils, causing the substrate 618 to be inductively heated.

Thus, in some embodiments, a substrate processing tool is provided. The substrate processing tool includes a housing defining a processing chamber. A substrate support is coupled to the housing and configured to support a substrate within the processing chamber. The substrate has a central axis. A first annular member is moveably coupled to the housing and positioned within the processing chamber. The first annular member circumscribes the central axis of the substrate. A second annular member is moveably coupled to the housing and positioned within the processing chamber. The second annular member circumscribes the central axis of the substrate. Movement of the first annular member and the second annular member relative to the housing changes a flow of processing fluid through the processing chamber.

In other embodiments, a method for processing a substrate is provided. A substrate processing tool is provided. The substrate processing tool includes a housing defining a processing chamber and a substrate support coupled to the housing and configured to support a substrate within the processing chamber. The substrate has a central axis. A first annular member is moved relative to the housing. The first annular member is positioned within the processing chamber and circumscribes the central axis of the substrate. A second annular member is moved relative to the housing. The second annular member is positioned within the processing chamber and circumscribes the central axis of the substrate. The movement of the first annular member relative to the housing and the movement of the second annular member relative to the housing changes a flow of processing fluid through the processing chamber.

In further embodiments, a substrate processing tool is provided. The substrate processing tool includes a housing defining a processing chamber. An enclosure is positioned within the housing. A substrate support is coupled to the housing and configured to support a substrate within the enclosure. The substrate has a central axis. A first annular member is moveably coupled to the housing and positioned within the enclosure. The first annular member circumscribes the central axis of the substrate and has a width greater than a width of the substrate support. A second annular member is moveably coupled to the housing and positioned within the enclosure. The second annular member circumscribes the central axis of the substrate and has a width greater than the width of the substrate support. Movement of the first annular member and the second annular member relative to the housing changes a flow of processing fluid through the enclosure.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A substrate processing tool comprising:
a housing defining a processing chamber;
a substrate support coupled to the housing and configured to support a substrate within the processing chamber, wherein the substrate has a planar surface and a central axis which is perpendicular to the planar surface;
a first annular member moveably coupled to the housing and positioned within the processing chamber, the first annular member circumscribing the central axis of the substrate; and
a second annular member moveably coupled to the housing and positioned within the processing chamber, the second annular member circumscribing the central axis of the substrate,
wherein the first annular member and the second annular member are moveable relative to the housing;
and wherein the first annular member and the second annular member are configured to vary a flow of processing fluid through the processing chamber.

2. The substrate processing tool of claim 1, wherein the first annular member is coupled to the housing such that the first annular member is vertically moveable within the processing chamber.

3. The substrate processing tool of claim 1, wherein the second annular member is coupled to the housing such that the second annular member is horizontally moveable within the processing chamber.

4. The substrate processing tool of claim 1, wherein the second annular member is coupled to the housing such that the angular orientation of the second annular member relative to the housing is adjustable.

5. The substrate processing tool of claim 1, further comprising an enclosure positioned within the processing chamber, the enclosure extending around a periphery of the substrate support, the first annular member, and the second annular member.

6. The substrate processing tool of claim 1, wherein the second annular member has a width that is greater than a width of the substrate support.

7. The substrate processing tool of claim 6, wherein the first annular member has a width that is greater than the width of the second annular member.

8. The substrate processing tool of claim 5, wherein the enclosure comprises a plurality of exhaust openings extending through the enclosure, wherein the plurality of exhaust openings are arranged around the central axis of the substrate.

9. The substrate processing tool of claim 8, wherein the plurality of exhaust openings are positioned below the substrate support.

10. The substrate processing tool of claim 9, further comprising a plurality of plugs, the plugs operable to at least partially restrict the flow through the exhaust openings, wherein each of the plurality of plugs is inserted into one of the plurality of exhaust openings.

11. A method for processing a substrate comprising:
providing a substrate processing tool comprising a housing defining a processing chamber and a substrate support coupled to the housing and configured to support a substrate within the processing chamber, wherein the substrate has a planar surface and a central axis which is perpendicular to the planar surface;
moving a first annular member relative to the housing, wherein the first annular member is positioned within the processing chamber and circumscribes the central axis of the substrate; and
moving a second annular member relative to the housing, wherein the second annular member is positioned within the processing chamber and circumscribes the central axis of the substrate,
wherein the movement of the first annular member relative to the housing and the movement of the second annular member relative to the housing varies a flow of processing fluid through the processing chamber.

12. The method of claim 11, wherein the second annular member has a width that is greater than a width of the substrate support.

13. The method of claim 12, wherein the first annular member has a width that is greater than the width of the second annular member.

14. The method of claim 13, wherein the movement of first annular member comprises moving the first annular member in a direction that is substantially parallel to the central axis of the substrate.

15. The method of claim 14, wherein the movement of second annular member comprises moving the second annular member in a direction that is substantially perpendicular to the central axis of the substrate.

16. The method of claim 15, wherein the substrate processing tool further comprises an enclosure within the processing chamber, the enclosure extending around a periphery of the substrate support, the first annular member, and the second annular member and comprising a plurality of exhaust openings extending therethrough, wherein the plurality of exhaust openings are arranged around the central axis of the substrate, and further comprising at least partially restricting the flow of processing fluid through at least some of the exhaust openings to further adjust the flow of processing fluid through the processing chamber.

17. A substrate processing tool comprising:
a housing defining a processing chamber;
an enclosure positioned within the housing;
a substrate support coupled to the housing and configured to support a substrate within the enclosure, wherein the substrate has a planar surface and a central axis which is perpendicular to the planar surface;
a first annular member moveably coupled to the housing and positioned within the enclosure, the first annular member circumscribing the central axis of the substrate and having a width greater than a width of the substrate support; and
a second annular member moveably coupled to the housing and positioned within the enclosure, the second annular member circumscribing the central axis of the substrate and having a width greater than the width of the substrate support,
wherein the first annular member and the second annular member are moveable relative to the housing;
and wherein the first annular member and the second annular member are configured to vary a flow of processing fluid through the processing chamber.

18. The substrate processing tool of claim 17, wherein the substrate processing tool further comprises a processing fluid inlet at an upper portion of the housing and configured to delivery processing fluid within the enclosure, and wherein the enclosure comprises a plurality of exhaust openings extending through the enclosure, wherein the plurality of exhaust openings are arranged around the central axis of the substrate.

19. The substrate processing tool of claim 18, further comprising a plurality of plugs, the plugs operable to at least partially restrict the flow through the exhaust openings, wherein each of the plurality of plugs is inserted into one of the plurality of exhaust openings.

20. The substrate processing tool of claim 19, wherein the first annular member is moveable relative to the housing in a direction that is substantially parallel with the central axis of the substrate, and wherein the second annular member is moveable relative to the housing in a direction that is substantially perpendicular.
